(19) United States
(12) Patent Application Publication
(10) Pub. No.: US 2025/0239573 A1
(43) Pub. Date: Jul. 24, 2025

(54) ARRANGEMENTS OF MULTIPLE-JUNCTION LIGHT-EMITTING DIODE CHIPS IN LIGHT-EMITTING DIODE PACKAGES AND RELATED DISPLAYS

(71) Applicant: CreeLED, Inc., Durham, NC (US)

(72) Inventors: Colin Blakely, Raleigh, NC (US); Michael Check, Holly Springs, NC (US); Robert David Schmidt, Wake Forest, NC (US)

(21) Appl. No.: 18/417,120

(22) Filed: Jan. 19, 2024

(51) Int. Cl. H01L 25/075; H01L 33/48; H01L 33/62

(52) U.S. Cl. CPC H01L 25/0753; H10H 20/8506; H10H 20/857

(57) ABSTRACT

Solid state light-emitting devices and more particularly arrangements of multiple-junction light-emitting diode (LED) chips in LED packages and corresponding LED displays are disclosed. Multiple-junction LED chips are arranged in LED packages with single-junction LED chips. Multiple-junction LED chips are configured to have forward voltages the same or similar to single-junction LED chips in the same LED package. Common anode or common cathode arrangements for multiple-junction and single-junction LED packages are disclosed. Multiple-junction LED chips configured to provide different emission wavelengths than single-junction LED chips while also having same or similar forward voltages are disclosed.

### FIELD OF THE DISCLOSURE

The present disclosure relates to solid state light-emitting devices and more particularly to arrangements of multiple-junction light-emitting diode (LED) chips in LED packages and related displays.

### BACKGROUND

Solid-state lighting devices such as light-emitting diodes (LEDs) are increasingly used in both consumer and commercial applications.

Advancements in LED technology have resulted in highly efficient and mechanically robust light sources with a long service life. Accordingly, modern LEDs have been widely adopted in various illumination contexts, for backlighting of liquid crystal display (LCD) systems (e.g., as a substitute for cold cathode fluorescent lamps), and for direct-view LED displays. Applications utilizing LED arrays further include vehicular headlamps, roadway illumination, light fixtures, and various indoor, outdoor, and specialty contexts. Desirable characteristics of LED devices include high luminous efficacy, long lifetime, and color gamut.

LEDs convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. Multiple color LED packages have been developed that include LED chips with different emission colors arranged within a same package structure. In certain applications, the LED chips can be arranged in close proximity to one another on a common submount, which can add complexity for corresponding electrical connections. As LED applications continue to advance, challenges exist in producing high quality light with desired emission characteristics while also providing high light emission efficiency.

The art continues to seek improved LEDs and solid-state lighting devices having desirable illumination characteristics capable of overcoming challenges associated with conventional lighting devices.

### SUMMARY

The present disclosure relates to solid state light-emitting devices and more particularly to arrangements of multiple-junction light-emitting diode (LED) chips in LED packages and corresponding LED displays. Multiple-junction LED chips are arranged in LED packages with single-junction LED chips. Multiple-junction LED chips are configured to have forward voltages the same or similar to single-junction LED chips in the same LED package. Common anode or common cathode arrangements for multiple-junction and single-junction LED packages are disclosed. Multiple-junction LED chips configured to provide different emission wavelengths than single-junction LED chips while also having same or similar forward voltages are disclosed.

In one aspect, an LED package comprises: a support element; at least one single-junction LED chip on the support element, the at least one single-junction LED chip comprising a first forward voltage; and at least one multiple-junction LED chip on the support element, the at least one multiple-junction LED chip comprising at least two light-emitting junctions, the at least two light-emitting junctions being electrically coupled in series, and the at least one multiple-junction LED chip comprising a second forward voltage that is within twenty five percent of the first forward voltage. In certain embodiments, the second forward voltage is within fifteen percent of the first forward voltage. The LED package may further comprise an electrically conductive element on the support element, the electrically conductive element forming a common anode connection or a common cathode connection for the at least one single-junction LED chip and the at least one multiple-junction LED chip. In certain embodiments, the support element is a submount with a plurality of patterned traces on a surface of the submount. In certain embodiments, the support element is a lead frame structure comprising a lead frame and housing, and the electrically conductive element is a single lead of the lead frame. In certain embodiments, the at least one single-junction LED chip and the at least one multiple-junction LED chip are electrically coupled with the electrically conductive element by way of a wire bond. In certain embodiments, at least one of the at least one single-junction LED chip and the at least one multiple-junction LED chip is flip-chip mounted and electrically coupled with the electrically conductive element. In certain embodiments, the support element comprises a lead frame structure, and the at least one single-junction LED chip is electrically coupled to a different pair of leads of the lead frame structure than the at least one multiple-junction LED chip. In certain embodiments: the at least one single-junction LED chip is configured to emit light of a first peak wavelength; and the at least one multiple-junction LED chip is configured to emit light of a second peak wavelength, and the second peak wavelength differs from the first peak wavelength by at least 20 nanometers (nm). The LED package may further comprise: an additional multiple-junction LED chip configured to emit light of a third peak wavelength that differs from the first peak wavelength and the second peak wavelength by at least 20 nm; and an additional single-junction LED chip configured to emit light of a fourth peak wavelength that differs from the first peak wavelength, the second peak wavelength, and the third peak wavelength by at least 20 nm; wherein the additional multiple-junction LED chip comprises a third forward voltage that is within twenty five percent of the first forward voltage and the second forward voltage.

In another aspect, an LED package comprises: a support element; at least one single-junction LED chip on the support element; at least one multiple-junction LED chip on the support element; and an electrically conductive element on the support element, the electrically conductive element forming a common anode connection or a common cathode connection for the at least one single-junction LED chip and the at least one multiple-junction LED chip. In certain embodiments, the support element is a submount and the electrically conductive element is a patterned trace on a surface of the submount. In certain embodiments, the support element is a lead frame structure comprising a lead frame and housing, and the electrically conductive element is a single lead of the lead frame. In certain embodiments, the support element comprises a lead frame structure, and the at least one single-junction LED chip is electrically coupled to a different pair of leads of the lead frame structure than the at least one multiple-junction LED chip. In certain embodiments, at least one of the at least one single-junction LED chip and the at least one multiple-junction LED chip is electrically coupled with the electrically conductive element by way of a wire bond. In certain embodiments, at least one of the at least one single-junction LED chip and the at least one multiple-junction LED chip is flip-chip mounted and electrically coupled with the electrically conductive element. In certain embodiments: the at least one single-junction LED chip is configured to emit light of a first peak wavelength; and the at least one multiple-junction LED chip is configured to emit light of a second peak wavelength, and the second peak wavelength differs from the first peak wavelength by at least 20 nanometers (nm). The LED package may further comprise: an additional multiple-junction LED chip configured to emit light of a third peak wavelength that differs from the first peak wavelength and the second peak wavelength by at least 20 nm; wherein the electrically conductive element forms the common anode connection or the common cathode connection for the single-junction LED chip, the multiple-junction LED chip, and the additional multiple-junction LED chip. The LED package may further comprise: an additional single-junction LED chip configured to emit light of a fourth peak wavelength that differs from the first peak wavelength, the second peak wavelength, and the third peak wavelength by at least 20 nm; wherein the electrically conductive element forms the common anode connection or the common cathode connection for the single-junction LED chip, the additional single-junction LED chip, the multiple-junction LED chip, and the additional multiple-junction LED chip.

In another aspect, an LED display comprises: a display panel; and at least one LED package comprising: at least one single-junction LED chip; and at least one multiple-junction LED chip, the at least one single-junction LED chip and the at least one multiple-junction LED chip forming a pixel of the display panel. In certain embodiments, at least one of the at least one single-junction LED chip and the at least one multiple-junction LED chip is electrically coupled to a common anode connection or a common cathode connection. In certain embodiments: the at least one single-junction LED chip comprises a first forward voltage; and the at least one multiple-junction LED chip comprises a second forward voltage that is within twenty five percent of the first forward voltage.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package with a multiple-junction LED chip having a forward voltage that is similar to one or more single-junction LED chips.

FIG. 1B is a cross-section of the LED package of FIG. 1A taken along the sectional line 1B-1B of FIG. 1A.

FIG. 1C is a cross-section of the LED package of FIG. 1A taken along the sectional line 1C-1C of FIG. 1A.

FIG. 2A is a top view of an LED package that is similar to the LED package of FIGS. 1A to 1C for flip-chip embodiments.

FIG. 2B is a cross-section of the LED package of FIG. 2A taken along the sectional line 2B-2B of FIG. 2A.

FIG. 2C is a cross-section of the LED package of FIG. 2A taken along the sectional line 20-2C of FIG. 2A.

FIG. 3 is a top view of an LED package that is similar to the LED package of FIGS. 1A to 1C for embodiments that include an additional multiple-junction LED chip and additional single-junction LED chips.

FIG. 4 is a top view of an LED package that is similar to the LED package of FIGS. 1A to 1C for embodiments that do not include a common anode or a common cathode connection.

FIG. 5A is a top view of an LED package that is similar to the LED package for embodiments where a support element for the LED package is a lead frame structure.

FIG. 5B is a top perspective view of the LED package of FIG. 5A with the LED chips omitted for illustrative purposes.

FIG. 6A is a top view of an LED package that is similar to the LED package of FIGS. 5A and 5B for embodiments that do not include a common anode or a common cathode connection.

FIG. 6B is a top perspective view of the LED package of FIG. 6A with the LED chips omitted for illustrative purposes.

FIG. 7 is a schematic diagram of a portion of an LED display screen, for example, an indoor and/or outdoor screen comprising LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid state light-emitting devices and more particularly to arrangements of multiple-junction light-emitting diode (LED) chips in LED packages and corresponding LED displays. Multiple-junction LED chips are arranged in LED packages with single-junction LED chips. Multiple-junction LED chips are configured to have forward voltages the same or similar to single-junction LED chips in the same LED package. Common anode or common cathode arrangements for multiple-junction and single-junction LED packages are disclosed. Multiple-junction LED chips configured to provide different emission wavelengths than single-junction LED chips while also having same or similar forward voltages are disclosed.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range in a range of 430 nanometers (nm) to 480 nm. In other embodiments, the active LED structure emits green light with a peak wavelength in a range of 500 nm to 570 nm. In other embodiments, the active LED structure emits orange and/or red light with a peak wavelength range of 600 nm to 700 nm. In still further embodiments, the active LED structure may emit cyan light with a peak wavelength in a range of 485 nm to 500 nm or violet light with a peak wavelength in a range from 400 nm to 420 nm. In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 700 nm to 1000 nm, or more.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure is applicable for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, multiple chip LED packages may include one or more elements, such as lumiphoric materials, encapsulants, light-altering materials, lenses, and electrical contacts, among others, that are provided along with multiple LED chips. In certain aspects, an LED package may include a support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure.

Aspects of the present disclosure relate to monolithic LED chips where multiple light-emitting junctions are formed on and supported by a common layer or a substrate. In this manner, a single LED chip may be referred to as a multiple-junction LED chip when multiple light-emitting junctions are arranged on a common layer or substrate of the single LED chip. The multiple light-emitting junctions may be electrically isolated from one another while also being formed from a common LED epitaxial structure. Certain embodiments include integral electrical connections that serially connect the multiple light-emitting junctions. In certain aspects, a common layer, when present, may be provided by a common epitaxial layer that is continuous across the multiple light-emitting junctions. In certain aspects, a common substrate may be provided by a common growth substrate on which the epitaxial structure is initially formed, where the common growth substrate is continuous across the multiple light-emitting junctions. Exemplary methods for forming a multiple-junction LED chip may include blanket epitaxial deposition of a continuous LED epitaxial structure at a wafer level, followed by electrically isolating individual junctions within the LED epitaxial structure. Individual multiple-junction LED chips may then be singulated from the wafer. In this manner, at least one of the common layer and the common substrate may remain in an individual multiple-junction LED chip to provide mechanical support for each of the corresponding junctions.

Sizes or areas of individual junctions of a multiple-junction LED chip may be scaled according to a desired emission intensity and profile. In certain embodiments, each junction may include a size in a range from smaller sizes such as 0.5 millimeters (mm) by 0.5 mm to larger sizes such as 2 mm by 2 mm, or other ranges from 0.5 mm by 0.5 mm to 1 mm by 1 mm. In certain embodiments, a longest lateral dimension of each junction may be in a range from 0.5 mm to 2 mm, or in a range from 1 mm to 2 mm, or in a range from 0.5 mm to 1 mm. In such ranges where at least one dimension is 0.5 mm and greater, the different junctions of a multiple-junction LED chip may be well suited for providing high output powers in a compact footprint. In certain aspects, spacing between different junctions may be smaller than what is possible for individual LED chips. In certain embodiments, a width of a street formed between individual junctions may be provided in a range from 20 microns (μm) to 200 μm, or in a range from 20 μm to 100 μm. Such smaller street widths may provide sharper contrast between neighboring junctions, particularly when light-altering materials are present, while also reducing any dark emission spots formed with larger conventional spacings. Larger street widths are also possible depending on the desired application.

LED packages have been developed that include multiple LED chips clustered together to provide increased light output and/or the capability for a single LED package to emit multiple colors and/or peak wavelengths of light. However, separately formed LED chips may have voltage requirements that vary, particularly for LED chips based on different material systems that emit different peak wavelengths. For example, blue and green emitting LED chips may be formed with gallium nitride-based materials and alloys thereof. Such blue and green LED chips typically have forward voltages, or turn-on voltages, in a range from 2.7 volts (V) to 3.5 V. In contrast, red and yellow LED chips may be formed with gallium phosphide-based materials and/or gallium arsenide-based materials. Such red and yellow LED chips typically have forward voltages in a range from 1.6 V to 1.8 V. Such variations may contribute to nonuniform light emissions and/or complex electrical connections to accommodate the different voltage requirements. Complex circuitry and/or separate drivers are commonly needed to accommodate different forward voltages in a common LED package. Moreover, differences in the forward voltages may generate heat and lead to associated power losses. Red and/or yellow LED chips may also appear generally dimmer compared to blue and/or green LED chips based on the human eye response to color differences.

According to aspects of the present disclosure, LED packages include at least one single junction LED chip and at least one multiple-junction LED chip with a forward voltage, or turn-on voltage, that is the same or close to a forward voltage of the at least one single junction LED chip. For example, a forward voltage of a multiple-junction LED chip may be within 25%, or within, or within 15%, or within 10%, or within 5%, or within 1% of a forward voltage of the at least one single junction LED chip within the same LED package. According to certain aspects, forward voltage values are current dependent and differences between different types of LED chips may be greater at higher operating currents. In certain embodiments, the above forward voltage percentage values between a multiple-junction LED chip and a single junction LED chip are provided at typical binning conditions and/or at higher operating currents. In certain aspects, multiple junctions within a multiple-junction LED chip are coupled in series to increase the effective forward voltage of the multiple-junction LED chip. By providing more closely matched forward voltages, LED packages may be formed with reduced complexity in electrical connections and all LED chips may be driven with a same driver. Additionally, more uniform emissions from different colored LED chips may be realized with more closely matched forward voltages.

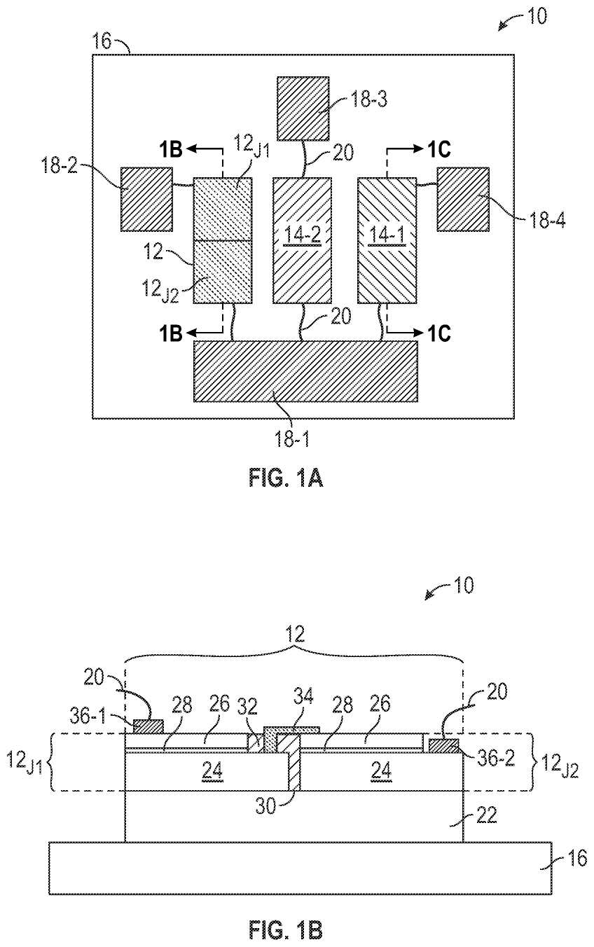

FIG. 1A is a top view of an LED package 10 with a multiple-junction LED chip 12 having a forward voltage that is similar to one or more single-junction LED chips 14-1, 14-2. The multiple-junction LED chip 12 and the single-junction LED chips 14-1, 14-2 are mounted on a common support element 16. In the context of the LED package 10, the support element 16 is illustrated as a submount of the LED package 10. In other embodiments, the principles described are equally applicable when the support element 16 forms a lead-frame structure with a lead frame and a corresponding housing. For the submount embodiment, electrically conductive elements in the form of a pattern of electrically conductive traces 18-1 to 18-4 are provided on a top surface of the support element 16. The electrically conductive traces 18-1 to 18-4 may form patterned traces for providing electrical connections to the multiple-junction LED chip 12 and the single-junction LED chips 14-1, 14-2.

As described above, different material systems for different wavelength LED emissions may have different forward voltage values. By way of example, the LED chip 14-1 may be configured to emit blue wavelengths and the LED chip 14-2 may be configured to emit green wavelengths, both of which have forward voltages in a range of 2.7 V to 3.5 V. In order for the LED package 10 to collectively emit various colors within a larger gamut space, red and/or yellow wavelengths are needed. For example, the multiple-junction LED chip 12 and the single junction LED chips 14-1 to 14-2 may each be configured to emit a unique peak wavelength that is at least 20 nm away from one another. As described above, materials systems for such emission wavelengths provide significantly different forward voltages, such as in a range of 1.6 V to 1.8 V. In FIG. 1A, the multiple-junction LED chip 12 is configured to emit red wavelengths and the multiple-junction LED chip 12 is subdivided into two LED junctions 12_{J1} and 12_{J2} that are serially coupled together. By coupling the two LED junctions 12_{J1} and 12_{J2} in series, the forward voltage of the multiple-junction LED chip 12 may effectively be doubled to more closely match the forward voltage of the single-junction LED chips 14-1, 14-2. For example, if both LED junctions 12_{J1} and 12_{J2} individually have forward voltages of 1.7 V, the multiple-junction LED chip 12 may now have an overall forward voltage of 3.4 V.

By more closely matching the forward voltages, the multiple-junction LED chip 12 may not require separate electrical considerations, such as separate drivers and associated electrical connections. In this manner, the multiple-junction LED chip 12 and the single-junction LED chips 14-1, 14-2 may be electrically coupled to a single electrically conductive element that forms a common anode or common cathode connection, such as the electrically conductive trace 18-1 in FIG. 1A. The other of the anode or cathode for each of the multiple-junction LED chip 12 and the single-junction LED chips 14-1, 14-2 may respectively be coupled to a different one of the traces 18-2 to 18-4 to provide individual addressability. In this regard, the multiple-junction LED chip 12 may be individually controlled by a same driver used to individually control the single-junction LED chips 14-1, 14-2. In certain embodiments, the multiple-junction LED chip 12 and the single-junction LED chips 14-1, 14-2 may be electrically coupled to the electrically conductive traces 18-1 to 18-4 by way of wire bonds 20.

FIG. 1B is a cross-section of the LED package 10 taken along the sectional line 1B-1B of FIG. 1A. In this regard, FIG. 1B provides a general cross-section of the multiple-junction LED chip 12 and corresponding LED junctions 12_{J1} and 12_{J2}. The LED junctions 12_{J1} and 12_{J2} are on a same face of a substrate 22 and the substrate 22 is mounted to the support element 16 of the LED package 10. In certain embodiments, the substrate 22 is a growth substrate on which the LED junctions 12_{J1} and 12_{J2} are formed. For example, an epitaxial structure including an n-type layer 24, a p-type layer 26, and an active layer 28 therebetween may be epitaxially grown before being subdivided into the LED junctions 12_{J1} and 12_{J2}. In this regard, each LED junction 12_{J1} and 12_{J2} includes separate portions of the same n-type layer 24, p-type layer 26, and active layer 28. A street 30 is formed between the LED junctions 12_{J1} and 12_{J2} and a passivation layer 32 may reside within the street 30 to provide electrical isolation. A metal contact 34 may extend at least partially through and even on a top surface of the passivation layer 32 to electrically couple the n-type layer 24 of the LED junction 12_{J1} to the p-type layer 26 of the LED junction 12_{J2}. In this manner, the LED junctions 12_{J1} and 12_{J2} are electrically coupled in series within the multiple-junction LED chip 12. A first bond pad 36-1 on the p-type layer 26 of the LED junction 12_{J1} and a second bond pad 36-2 on the n-type layer 24 of the LED junction 12_{J2} provide contact points for the wire bonds 20.

For comparison, FIG. 1C is a cross-section of the LED package 10 taken along the sectional line 10-1C of FIG. 1A. In this regard, FIG. 1C provides a general cross-section of the single-junction LED chip 14-1. The single-junction LED chip 14-1 includes a substrate 38, an n-type layer 40, a p-type layer 42, and an active layer 44 between the n-type layer 40 and the p-type layer 42. In this manner, the LED chip 14-1 has a single LED junction 14-1_{J1}. A first bond pad 46-1 on the p-type layer 42 and a second bond pad 46-2 on the n-type layer 40 of the LED junction 14-1_{J1} provide contact points for the wire bonds 20.

With reference to FIGS. 1A to 1C, the second bond pad 46-2 of the single LED junction 14-1_{J1} (FIG. 1C) and the second bond pad 36-2 of the LED junction 12_{J2} (FIG. 1B) are coupled to the same electrically conductive trace 18-1 (FIG. 1A). To provide individual addressability, the first bond pad 46-1 of the single LED junction 14-1_{J1} (FIG. 1C) and the first bond pad 36-1 of the LED junction 12_{J1} (FIG. 1B) are coupled to different ones of electrically conductive traces 18-2 to 18-4 (FIG. 1A).

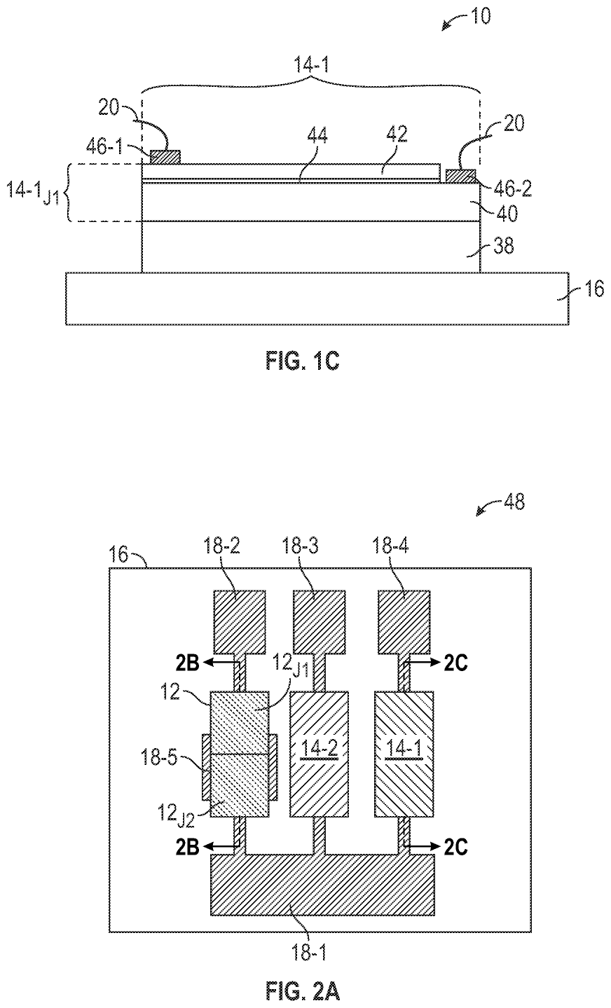

FIG. 2A is a top view of an LED package 48 that is similar to the LED package 10 of FIGS. 1A to 1C for flip-chip embodiments. In this manner, one or more of the multiple-junction LED chip 12 and the single-junction LED chips 14-1, 14-2 may comprise flip-chip configurations that are electrically coupled to the electrically conductive traces 18-1 to 18-5 without the use of wire bonds. As illustrated, portions of the electrically conductive traces 18-1 to 18-5 extend underneath corresponding portions of the multiple-junction LED chip 12 and the single-junction LED chips 14-1, 14-2.

FIG. 2B is a cross-section of the LED package 48 taken along the sectional line 2B-2B of FIG. 2A. In this regard, FIG. 2B provides a general cross-section of the multiple-junction LED chip 12 and corresponding LED junctions 12_{J1} and 12_{J2} in a flip-chip arrangement on the support element 16. In this regard, the p-type layer 26 of the LED junction 12_{J1} is mounted and electrically coupled to the electrically conductive trace 18-2, and the n-type layer 24 of the LED junction 12_{J2} is electrically coupled to the electrically conductive trace 18-1. In certain embodiments, an interconnection 50 is formed to provide an electrically conductive path through the passivation layer 32 between the electrically conductive trace 18-1 and the n-type layer 24. The electrically conductive trace 18-5 is provided on the support element 16 to facilitate serial coupling of the LED junctions 12_{J1} and 12_{J2}. In this manner, the electrically conductive trace 18-5 may be coupled between the n-type layer 24 of the LED junction 12_{J1} and the p-type layer 26 of the LED junction 12_{J2}. Another interconnection 50 may be provided through the passivation layer 32 to form an electrically conductive path between the n-type layer 24 and the electrically conductive trace 18-5.

For comparison, FIG. 2C is a cross-section of the LED package 48 taken along the sectional line 20-2C of FIG. 2A. In this regard, FIG. 2C provides a general cross-section of the single-junction LED chip 14-1 in a flip-chip arrangement on the support element 16.

With reference to FIGS. 2A to 2C, the n-type layer 40 of the single LED junction 14-1_{J1} (FIG. 2C) and the n-type layer 24 of the LED junction 12_{J2} (FIG. 2B) are flip-chip mounted and electrically coupled to the same electrically conductive trace 18-1. To provide individual addressability, the p-type layer 42 of the single LED junction 14-1_{J1} (FIG. 2C) and the p-type layer 26 of the LED junction 12_{J1} (FIG. 2B) are flip-chip mounted and electrically coupled to different ones of electrically conductive traces 18-2 to 18-4 (FIG. 2A).

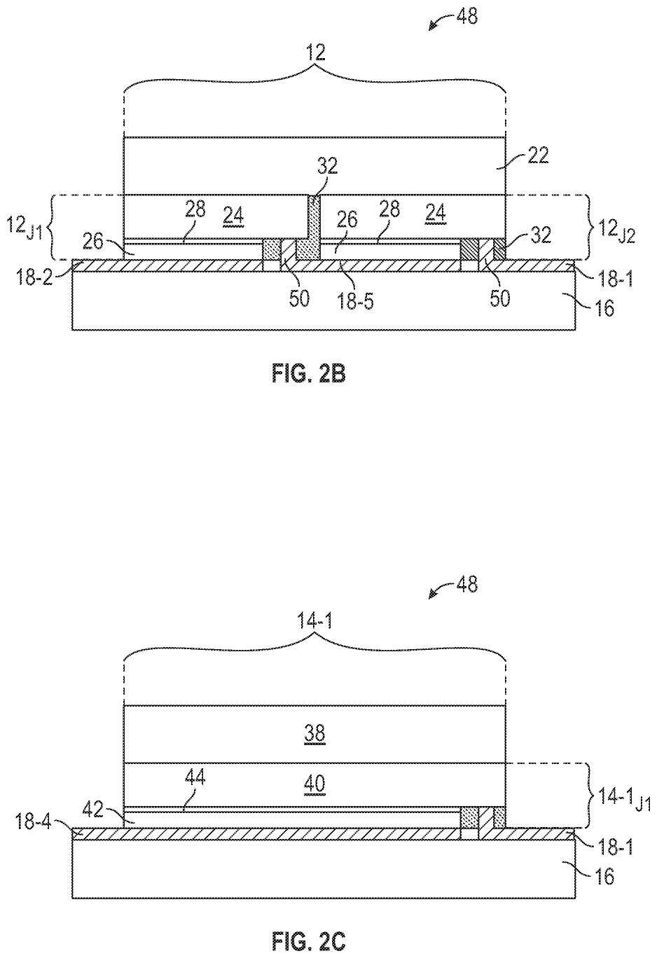

FIG. 3 is a top view of an LED package 52 that is similar to the LED package 10 of FIGS. 1A to 1C for embodiments that include an additional second multiple-junction LED chip 54 and additional single-junction LED chips 14-1 to 14-4. By adding additional LED chips, the LED package 10 may include the capability of emitting additional wavelengths that increase a color gamut of aggregate emissions. Exemplary additional wavelengths include yellow, cyan, amber, additional blue wavelengths such as longer wavelength blue, and/or additional red wavelengths such as longer wavelength red. Moreover, the multiple-junction LED chips 12, 54 and the single-junction LED chips 14-1 to 14-4 may be configured with forward voltages that are the same or similar, regardless of emission color, to provide the ability to drive all with a common LED driver. By way of example, each of the multiple-junction LED chips 12, 54 and the single-junction LED chips 14-1 to 14-4 may have a forward voltage that is within 10% or within 5% of one another. In this manner, each of the multiple-junction LED chips 12, 54 and the single-junction LED chips 14-1 to 14-4 may be electrically coupled to the same electrically conductive trace 18-1 for a common anode or a common cathode configuration. In certain embodiments, each of the multiple-junction LED chips 12, 54 and the single junctions LED chips 14-1 to 14-4 may be configured to emit a unique peak wavelength that is at least 20 nm away from one another.

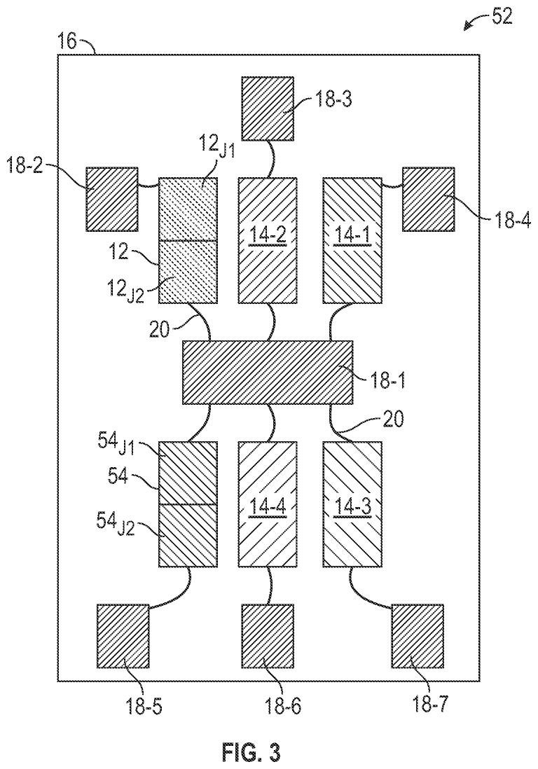

FIG. 4 is a top view of an LED package 56 that is similar to the LED package 10 of FIGS. 1A to 1C for embodiments that do not include a common anode or a common cathode connection. As illustrated, the multiple-junction LED chip 12 is electrically coupled between the electrically conductive traces 18-1 and 18-2, the single-junction LED chip 14-1 is electrically coupled between the electrically conductive traces 18-4 and 18-6, and the single-junction LED chip 14-2 is electrically coupled between the electrically conductive traces 18-3 and 18-5. Accordingly, the multiple-junction LED chip 12 and the single-junction LED chips 14-1, 14-2 may be individually addressable without the common anode or common cathode configuration.

As indicated above, the principles of the present disclosure are equally applicable to LED packages where support elements embody lead frame structures. A lead frame structure typically includes a lead frame with a number of metal leads and a housing. The leads are embedded within the housing and the LED chips are electrically coupled to portions of the leads accessible within an opening or recess of the LED package. O the portions of the leads may extend outside of the housing to receive external electrical connections. In this manner, the principles of the present disclosure, including all of FIGS. 1A to 4, are applicable to lead frame structures where the electrically conductive traces are replaced by leads of a lead frame.

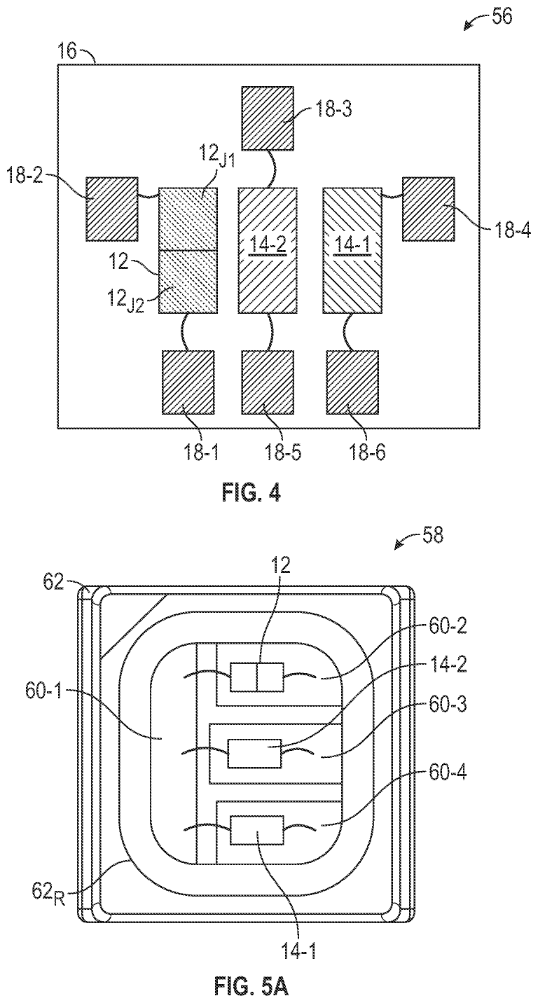

FIG. 5A is a top view of an LED package 58 that is similar to the LED package 10 for embodiments where a support element for the LED package 58 is a lead frame structure. FIG. 5B is a top perspective view of the LED package 58 of FIG. 5A with the LED chips omitted for illustrative purposes. The LED package 58 is a lead frame package that includes a lead frame structure formed by leads 60-1 to 60-4 within a housing 62. The multiple-junction LED chip 12 and the single-junction LED chips 14-1, 14-2 reside within a recess 62R of the housing 62 and are mounted and/or electrically coupled to portions of the leads 60-1 to 60-4 exposed at a bottom or floor of the recess 62R. In FIG. 5A, wire bond connections are shown in a similar manner to FIG. 1A; however, flip-chip arrangements as shown in FIG. 2A are also applicable. With same or similar forward voltages, each of the multiple-junction LED chip 12 and the single-junction LED chips 14-1, 14-2 may be coupled to a common lead 60-1 for a common anode or a common cathode configuration. FIG. 5B is from the perspective of the common lead 60-1 exiting the LED package 58.

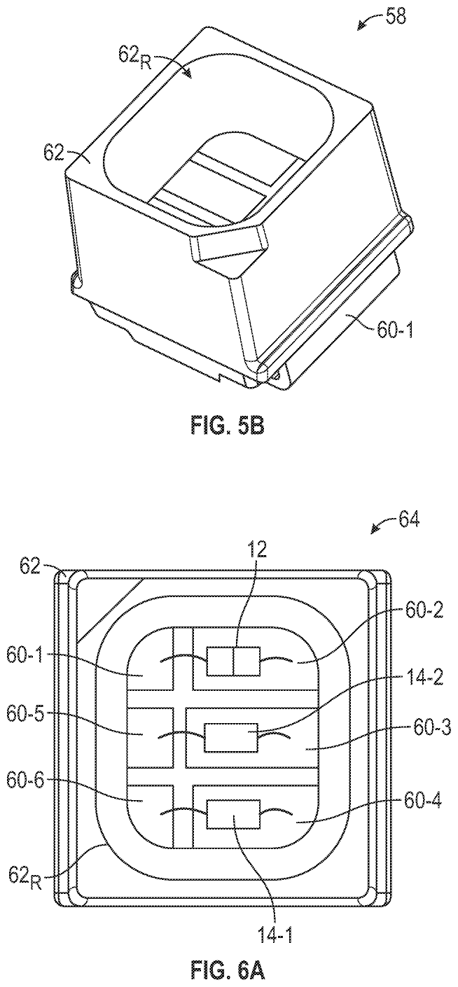

FIG. 6A is a top view of an LED package 64 that is similar to the LED package 58 of FIGS. 5A and 5B for embodiments that do not include a common anode or a common cathode connection. FIG. 6B is a top perspective view of the LED package 64 of FIG. 6A with the LED chips omitted for illustrative purposes. For the LED package 64, additional leads 60-5 and 60-6 are provided such that each of the multiple-junction LED chip 12 and the single-junction LED chips 14-1, 14-2 are coupled to a different pair of the leads 60-1 to 60-6.

Any of the embodiments of the present disclosure, including FIGS. 1A to 6B, may be well suited for arrangement in LED display applications. Each LED package with a combination of one or more multiple-junction LED chips and one or more single-junction LED chips may be arranged as LED pixels in such display applications. The same or similar forward voltages as described herein may allow more uniform emissions from such LED displays with reduced complexity for LED drivers.

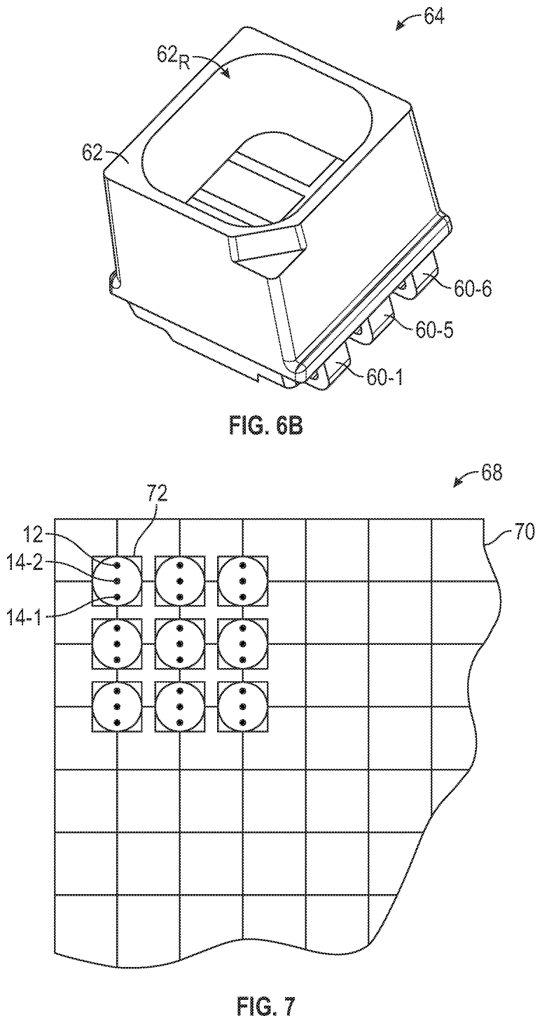

FIG. 7 is a schematic diagram of a portion of an LED display screen 68, for example, an indoor and/or outdoor screen comprising, in general terms, a display panel including a driver printed circuit board (PCB) 70 carrying a large number of surface-mount devices (SMDs) 72 arranged in rows and columns, each SMD 72 defining a pixel. The SMDs 72 may comprise LED packages according to any of the embodiments described here for FIGS. 1A to 6B. The SMDs 72 are electrically connected to traces or pads on the PCB 70 to respond to appropriate electrical signal processing and driver circuitry (not shown). It is to be appreciated that while FIG. 7 depicts the multiple-junction LED chip 12 and the single-junction LED chips 14-1, 14-2 in a linear arrangement, in other embodiments, the multiple-junction LED chip 12 and the single-junction LED chips 14-1, 14-2 may be arranged in different layouts.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support element;
at least one single-junction LED chip on the support element, the at least one single-junction LED chip comprising a first forward voltage; and
at least one multiple-junction LED chip on the support element, the at least one multiple-junction LED chip comprising at least two light-emitting junctions, the at least two light-emitting junctions being electrically coupled in series, and the at least one multiple-junction LED chip comprising a second forward voltage that is within twenty five percent of the first forward voltage.

2. The LED package of claim 1, wherein the second forward voltage is within fifteen percent of the first forward voltage.

3. The LED package of claim 1, further comprising an electrically conductive element on the support element, the electrically conductive element forming a common anode connection or a common cathode connection for the at least one single-junction LED chip and the at least one multiple-junction LED chip.

4. The LED package of claim 3, wherein the support element is a submount with a plurality of patterned traces on a surface of the submount.

5. The LED package of claim 3, wherein the support element is a lead frame structure comprising a lead frame and housing, and the electrically conductive element is a single lead of the lead frame.

6. The LED chip of claim 3, wherein the at least one single-junction LED chip and the at least one multiple-junction LED chip are electrically coupled with the electrically conductive element by way of a wire bond.

7. The LED package of claim 3, wherein at least one of the at least one single-junction LED chip and the at least one multiple-junction LED chip is flip-chip mounted and electrically coupled with the electrically conductive element.

8. The LED package of claim 1, wherein the support element comprises a lead frame structure, and the at least one single-junction LED chip is electrically coupled to a different pair of leads of the lead frame structure than the at least one multiple-junction LED chip.

9. The LED package of claim 1, wherein:
the at least one single-junction LED chip is configured to emit light of a first peak wavelength; and
the at least one multiple-junction LED chip is configured to emit light of a second peak wavelength, and the second peak wavelength differs from the first peak wavelength by at least 20 nanometers (nm).

10. The LED package of claim 9, further comprising:
an additional multiple-junction LED chip configured to emit light of a third peak wavelength that differs from the first peak wavelength and the second peak wavelength by at least 20 nm; and
an additional single-junction LED chip configured to emit light of a fourth peak wavelength that differs from the first peak wavelength, the second peak wavelength, and the third peak wavelength by at least 20 nm;
wherein the additional multiple-junction LED chip comprises a third forward voltage that is within twenty five percent of the first forward voltage and the second forward voltage.

11. A light-emitting diode (LED) package comprising:
a support element;
at least one single-junction LED chip on the support element;
at least one multiple-junction LED chip on the support element; and
an electrically conductive element on the support element, the electrically conductive element forming a common anode connection or a common cathode connection for the at least one single-junction LED chip and the at least one multiple-junction LED chip.

12. The LED package of claim 11, wherein the support element is a submount and the electrically conductive element is a patterned trace on a surface of the submount.

13. The LED package of claim 11, wherein the support element is a lead frame structure comprising a lead frame and housing, and the electrically conductive element is a single lead of the lead frame.

14. The LED package of claim 11, wherein the support element comprises a lead frame structure, and the at least one single-junction LED chip is electrically coupled to a different pair of leads of the lead frame structure than the at least one multiple-junction LED chip.

15. The LED package of claim 11, wherein at least one of the at least one single-junction LED chip and the at least one multiple-junction LED chip is electrically coupled with the electrically conductive element by way of a wire bond.

16. The LED package of claim 11, wherein at least one of the at least one single-junction LED chip and the at least one multiple-junction LED chip is flip-chip mounted and electrically coupled with the electrically conductive element.

17. The LED package of claim 11, wherein:
the at least one single-junction LED chip is configured to emit light of a first peak wavelength; and
the at least one multiple-junction LED chip is configured to emit light of a second peak wavelength, and the second peak wavelength differs from the first peak wavelength by at least 20 nanometers (nm).

18. The LED package of claim 17, further comprising:
an additional multiple-junction LED chip configured to emit light of a third peak wavelength that differs from the first peak wavelength and the second peak wavelength by at least 20 nm;
wherein the electrically conductive element forms the common anode connection or the common cathode connection for the single-junction LED chip, the multiple-junction LED chip, and the additional multiple-junction LED chip.

19. The LED package of claim 18, further comprising:
an additional single-junction LED chip configured to emit light of a fourth peak wavelength that differs from the first peak wavelength, the second peak wavelength, and the third peak wavelength by at least 20 nm;
wherein the electrically conductive element forms the common anode connection or the common cathode connection for the single-junction LED chip, the additional single-junction LED chip, the multiple-junction LED chip, and the additional multiple-junction LED chip.

20. A light-emitting diode (LED) display comprising:
a display panel; and
at least one LED package comprising:
at least one single-junction LED chip; and
at least one multiple-junction LED chip, the at least one single-junction LED chip and the at least one multiple-junction LED chip forming a pixel of the display panel.

21. The LED display of claim 20, wherein at least one of the at least one single-junction LED chip and the at least one multiple-junction LED chip is electrically coupled to a common anode connection or a common cathode connection.

22. The LED display of claim 20, wherein:
the at least one single-junction LED chip comprises a first forward voltage; and
the at least one multiple-junction LED chip comprises a second forward voltage that is within twenty five percent of the first forward voltage.
